(19) United States
(12) Patent Application Publication
(10) Pub. No.: US 2014/0239385 A1
(43) Pub. Date: Aug. 28, 2014

(54) FIELD EFFECT TRANSISTOR AND METHOD OF MANUFACTURING THE SAME

(71) Applicant: INSTITUTE OF MICROELECTRONICS, CHINESE ACADEMY OF SCIENCES, Beijing (CN)

(72) Inventors: Jinshun Bi, Beijing (CN); Chaohe Hai, Beijing (CN); Zhengsheng Han, Beijing (CN); Jiajun Luo, Beijing (CN)

(73) Assignee: INSTITUTE OF MICROELECTRONICS, CHINESE ACADEMY OF SCIENCES, Beijing (CN)

(21) Appl. No.: 14/346,223

(22) PCT Filed: Sep. 21, 2012
(86) PCT No.: PCT/CN2012/081749

§ 371 Date: Mar. 20, 2014

(30) Foreign Application Priority Data
Sep. 23, 2011 (CN) 201110285830.X

(51) Int. Cl. H01L 29/78; H01L 29/66

(52) U.S. Cl. CPC H01L 29/7834; H01L 29/66666; H01L 29/7835
USPC 257/329; 438/268

(57) ABSTRACT

A Field Effect Transistor (FET) and a method of manufacturing the same are provided. The FET may include a substrate; a source and a drain, one of which is formed on a bulge formed on a top surface of the substrate, and the other of which is formed in the substrate below but laterally offset from the bulge; a gate formed at a position where the bulge and the top surface of the substrate join each other; and a gate dielectric layer formed between the gate and the bulge and also between the gate and the top surface of the substrate. The FET has a vertical configuration, where the source is disposed on top of the bulge while the drain is disposed in the substrate, that is, the source and the drain are not in one same plane. As a result, the FET may have its area significantly reduced. Therefore, it is possible to improve an integration density of an IC and thus reduce cost.

### TECHNICAL FIELD

The present disclosure relates to the microelectronics field, and particularly, to a field effect transistor and a method of manufacturing the same.

### BACKGROUND

Field Effect Transistors (FETs) are fundamental devices for Integrated Circuits (ICs), and have a wide range of applications in the microelectronics field. FIG. 1 is a view schematically showing a configuration of a conventional FET. As shown in FIG. 1, the FET comprises a substrate 101, with a well region 102 formed therein. A gate G, a drain D, a source S, and Lightly Doped Drain (LDD) regions 104 are disposed in an active region defined by the well region 102. A gate dielectric layer 103 is provided between the gate G and the substrate 101, and oxide spacers 105 are provided on sidewalls of the gate G of polysilicon. If a particular voltage is applied to the gate G, a number of carriers will be accumulated in a portion of the substrate beneath the gate G for conduction, resulting in a conductive path between the source S and the drain D. The conductive path causes a drain current under a voltage between the drain D and the source S. As shown in FIG. 1, the conventional FET has a planar configuration, that is, the source S and the drain D are substantially in one same plane.

### SUMMARY

With the development of the microelectronics science and technology, higher and higher integration density is needed. It is desirable to effectively improve the integration density of the ICs while ensuring performance thereof. However, the conventional FET has limits in reduction of its area due to the configuration where the source S and the drain D are substantially in the same plane.

### Problems to be Solved

To address one or more of the above described problems, there is provided a Field Effect Transistor (FET) and a method of manufacturing the same, to reduce an area of the FET.

### Solutions

According to an aspect of the present disclosure, there is provided a Field Effect Transistor (FET), comprising: a substrate with a bulge formed on a top surface thereof; a source and a drain, one of which is formed on the bulge formed on the top surface of the substrate, and the other of which is formed in the substrate at a location below, but laterally offset, from the bulge; a gate formed at a position where the bulge and the top surface of the substrate join each other; and a gate dielectric layer formed between the gate and the bulge and also between the gate and the top surface of the substrate.

According to a further aspect of the present disclosure, there is provided a method of manufacturing an FET, the method comprising: forming a bulge on a substrate; forming a gate at a position where the bulge and a top surface of the substrate join each other, with a gate dielectric layer sandwiched between the gate and the bulge and also between the gate and the top surface of substrate; and forming one of a source and a drain of the FET on the bulge, and forming the other of the source and the drain in the substrate at a location below, but laterally offset, from the bulge.

### Advantageous Effects

According to embodiments of the present disclosure, the FET has a vertical configuration, where the source is disposed on top of the bulge while the drain is disposed in the substrate, that is, the source S and the drain D are not in one same plane. As a result, the FET may have its area significantly reduced. Therefore, it is possible to improve an integration density of an Integrated Circuit (IC) by a factor of about two. In other words, a circuit die can have its footprint reduced by a factor of about two as compared with a conventional circuit die for achieving the same function, resulting in significantly reduced cost.

Further, according to embodiments of the present disclosure, the gate and the source are disposed vertically, and the drain is disposed horizontally. As a result, it is possible to effectively reduce a drain-side peak electric field, suppress drain-induced barrier-lowering effects, improve resistance to punch-through, suppress hot carrier effects, and/or improve reliability of the FET.

Further, the FET and the manufacturing method thereof are compatible with conventional processes, and thus are ready for mass production.

### BRIEF DESCRIPTION OF THE DRAWINGS

FIG. 1 is a view schematically showing a configuration of a conventional Field Effect Transistor (FET);

FIG. 2 is a view schematically showing a configuration of a FET according to an embodiment of the present disclosure;

FIG. 3 is a view schematically showing a configuration of a FET according to a further embodiment of the present disclosure;

FIG. 4 is a flowchart showing a method of manufacturing a FET according to an embodiment of the present disclosure;

FIG. 5 is a flowchart showing a method of manufacturing a FET according to an embodiment of the present disclosure in detail; and

FIG. 6 shows structures resulting from respective operations of FIG. 5.

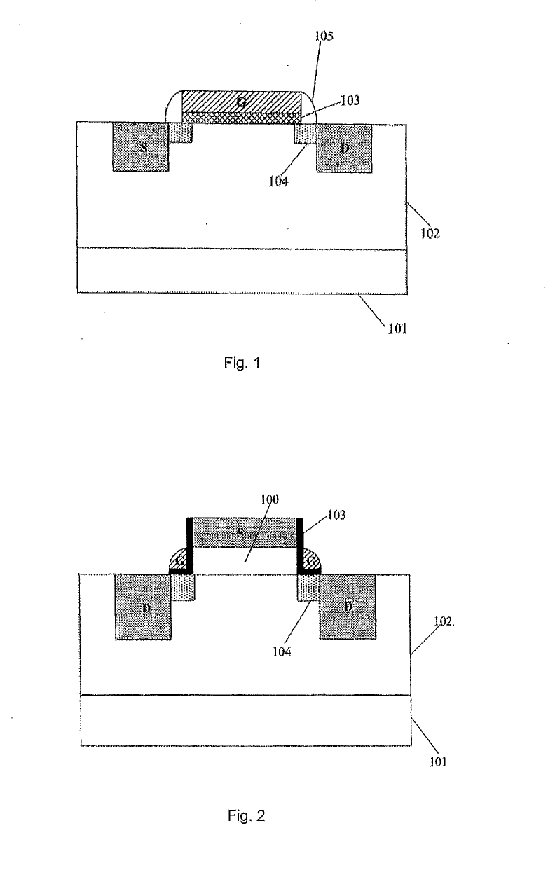

### DETAILED DESCRIPTION

Objects, features and advantages of the present disclosure will become apparent from the following descriptions of some embodiments of the present disclosure, with reference to the attached drawings. The present disclosure may contain illustration of parameters with specific values. However, it is to be understood that it is not necessary for the parameters to be exactly the respective values, but the parameters can approximate the respective values within an acceptable tolerance or design constraint.

According to an exemplary embodiment of the present disclosure, there is provided a Field Effect Transistor (FET). FIG. 2 is a view schematically showing a configuration of a FET according to an embodiment of the present disclosure. As shown in FIG. 2, the FET may comprise a substrate 101 with a bulge 100 formed on a top surface thereof, a source S formed on the bulge 100, a drain D formed in the substrate at a location below, but laterally offset from, the bulge 100 and having a top surface substantially flush with the top surface of the substrate, a gate G formed at a position where the bulge 100 and the top surface of the substrate 101 join each other, and a gate dielectric layer 103 formed between the gate G and the bulge 100 and also between the gate G and the top surface of the substrate 101.

In the FET of FIG. 2, if a particular voltage is applied to the gate G, a number of carriers will be accumulated in a portion of the bulge 100 beneath the source S and also in a portion of the substrate 101 beneath the bulge 100 for conduction, resulting in a conductive path between the source S and the drain D. The conductive path causes a drain current under a voltage between the drain D and the source S, leading to an ON state of the FET.

According to an embodiment, a well region 102 may be formed in the substrate 101, and the drain D may be formed in the well region 102. Of course, the present disclosure is not limited thereto. According to a further embodiment, the drain D may be formed directly in the substrate 101. The well region 102 formed in the substrate 101 helps provide better adjustment of a threshold voltage so that there is a compromise between an on current and an off current of the device. However, the well region is not necessary.

According to an embodiment, the FET may further comprise a LDD region 104 formed in the substrate 101 at a location below a portion of the gate dielectric layer 103 between the gate G and the top surface of the substrate 101 and adjoining the drain D. The LDD configuration is generally applicable to sub-micron FETs to, for example, suppress hot carrier effects and/or improve voltage withstanding performance. However, the LDD region is not necessary.

The substrate 101 may comprise a silicon based substrate, but is not limited thereto. The substrate 101 may comprise other materials, such as germanium. The substrate 101 may be n- or p-doped. The gate G may comprise polysilicon.

In a case where the FET is an n-channel FET, the well region 102 may be p-doped, the source S and the drain D may be heavily n-doped, and the LDD region 104 may be lightly n-doped. Alternatively, in a case where the FET is a p-channel FET, the well region 102 may be n-doped, the source S and the drain D may be heavily p-doped, and the LDD region 104 may be lightly p-doped.

It is to be noted that the heavily doped drain, if disposed to have its sidewall aligned with a corresponding sidewall of the bulge, will impact doping of a channel. Thus, the drain is desirably disposed at a location below, but laterally offset from, the gate dielectric, as shown in FIG. 2. Further, the source S and the drain D are exchangeable, and if exchanged, will not prevent the FET from properly operating.

In FIG. 2, the top surface of the drain D is substantially flush with the top surface of the substrate. However, it is not necessary for them to be flush with each other. For example, a configuration where the top surface of the drain D may be slightly higher or slightly lower than the top surface of the substrate is also applicable, and is included in the present disclosure.

In the embodiment shown in FIG. 2 there may be two drains D disposed substantially symmetrically with respect to the bulge 100. That is, the drains D are formed in the substrate 101 on opposite sides of the bulge 100. The symmetrically disposed drains D can improve driving capability per area of the device.

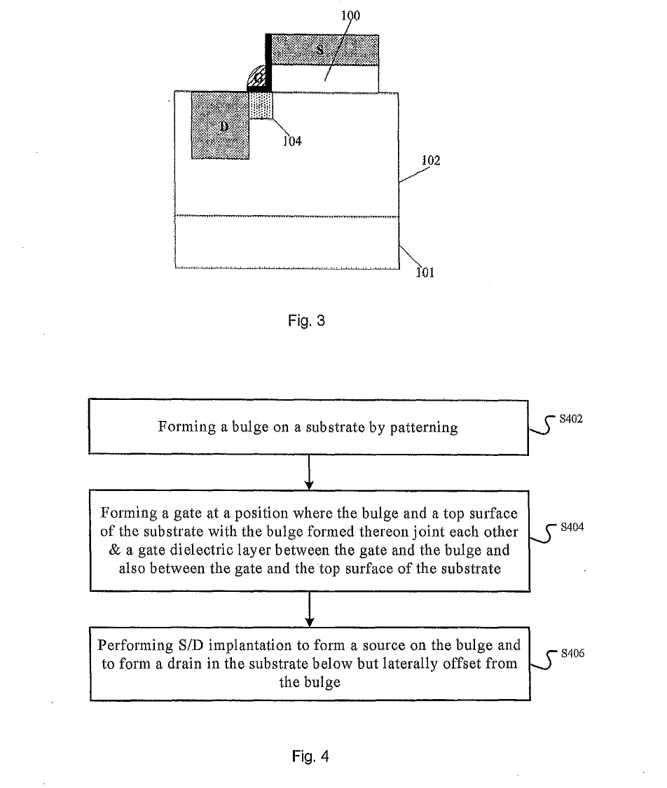

FIG. 3 is a view schematically showing a configuration of an FET according to a further embodiment of the present disclosure. This FET is substantially the same in configuration as that shown in FIG. 2, except that the drain D is disposed only on a single side of the bulge 100 of the substrate 101. Likewise, the source S and the drain D of the FET are not in one same plane. Because the drain D is disposed only on one side of the bulge 100, the FET is further reduced in area. Besides the above differences, the FET of FIG. 3 is the same as the FET of FIG. 2, and detailed descriptions thereof are omitted here.

According to the embodiments of the present disclosure, the FET has a vertical configuration, where the source S and the drain D are not in one same plane. For example, the source S may be disposed on the bulge 100, while the drain D may be disposed in the substrate. The FET in this configuration has its area significantly reduced. If FETs in such a configuration are applied to an Integrated Circuit (IC), the IC can have its integration density improved by a factor of about two. In other words, a circuit die can have its footprint reduced by a factor of about two as compared with a conventional circuit die for achieving the same function, resulting in significantly reduced cost.

Further, according to the embodiments of the present disclosure, the gate G and the source S are disposed vertically, and the drain D is disposed horizontally. As a result, it is possible to effectively reduce a drain-side peak electric field, suppress drain-induced barrier-lowering effects, improve resistance to punch-through, suppress hot carrier effects, and/or improve reliability of the FET.

Further, there is also provided a method of manufacturing a FET. As shown in FIG. 4, the method may start at operation S402 of forming a bulge on a substrate by a patterning process. The patterning process may comprise at least one of photolithography, etching, stripping off, and/or the like.

Then, the method may proceed to operation S404 of forming a gate at a position where the bulge and a top surface of the substrate with the bulge formed thereon join each other, and forming a gate dielectric layer between the gate and the bulge and also between the gate and the top surface of the substrate.

Next, the method may proceed to operation S406 of performing source/drain implantation to form a source on the bulge and to form a drain in the substrate at a location below, but laterally offset from, the bulge.

It is to be understood that the method may comprise further operations, such as formation of contact holes, formation of metal electrodes, and/or passivation.

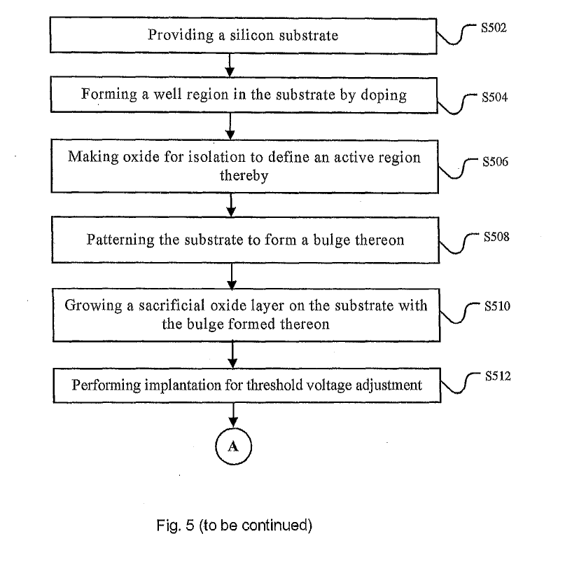

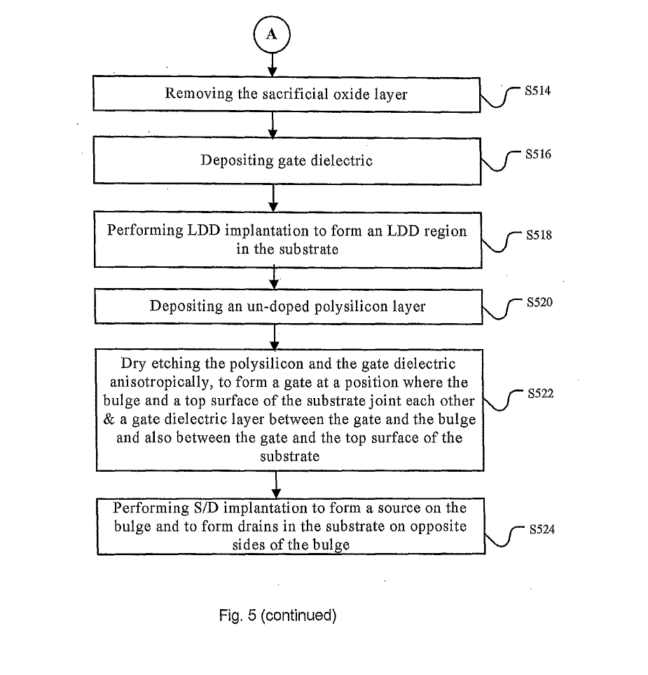

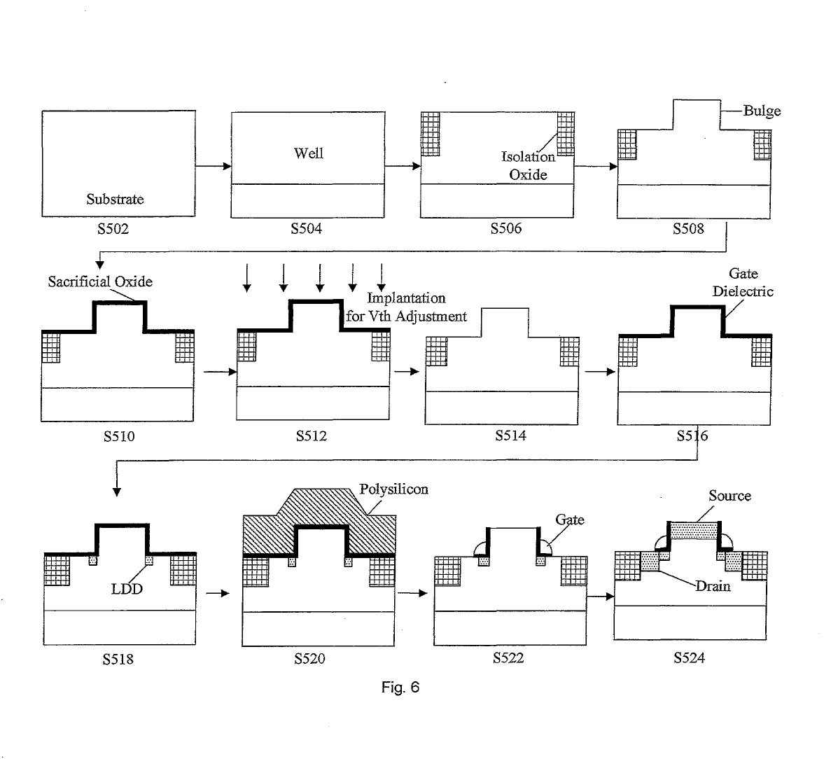

FIG. 5 is a flowchart showing a method of manufacturing a FET according to an embodiment of present disclosure in detail, and FIG. 6 shows structures resulting from respective operations of FIG. 5. In the following, the method is described in detail with reference to FIG. 5, in conjunction with FIGS. 2 and 6.

As shown in FIG. 5, the method may start at operation S502 of providing a silicon substrate. The silicon substrate may be n- or p-doped to have a resistivity of about 1-20 Ω·cm, and may have a crystal orientation of (100).

Next, the method may proceed to operation S504 of forming a well region in the substrate by doping, and then operation S506 of forming isolation oxide for isolation of the FET to define an active region thereby. More specifically, regions of the substrate other than the isolation oxide define the active region, and the FET will be formed in the active region. The isolation oxide may be formed by Local Oxidation of Silicon (LOCOS) or Shallow Trench Isolation (STI), with the active region covered by an active region mask.

Then, the method may proceed to operation S508 of patterning the substrate to form a bulge thereon. The patterning may comprise at least one of photolithography, etching, stripping off, and/or the like. Specifically, the substrate may be subjected to dry etching by chlorine based gas, with a source region covered by a source mask. The etching may be performed to a depth of about 100 nm-500 nm, resulting in the bulge on the substrate.

Subsequently, the method may proceed to operation S510 of growing a sacrificial oxide layer on the substrate with the bulge formed thereon. Specifically, the sacrificial oxide layer may be formed by wet oxygen oxidation or dry oxygen oxidation to a thickness of about 5 nm-20 nm.

The method may comprise operation S512 of performing implantation on the substrate with the bulge formed thereon for threshold voltage adjustment. The implantation is performed to adjust the threshold voltage, to achieve a compromise between an on current and an off current of the FET. For high performance applications, a relatively low threshold voltage is desirable so that the on and off currents are both increased. For low performance applications, a relatively high threshold voltage is desirable so that the on and off currents are both reduced.

Further, the implantation may be performed on a region slightly greater than the well region, so that the whole well region is subjected to the implantation to guarantee overlay accuracy.

In a case where the FET is an n-channel FET, an impurity, such as boron, may be implanted at an energy of about 10 keV-200 keV and at a dose of 1E11 cm⁻²-1E13 cm⁻². In a case where the FET is a p-channel FET, an impurity, such as phosphor, may be implanted at an energy of about 10 keV-200 keV and at a dose of 1E11 cm⁻²-1E13 cm⁻².

Then, the method may proceed to operation S514 of removing the sacrificial oxide layer, and then operation S516 of depositing a gate dielectric. The gate dielectric may have a thickness of about 1 nm-10 nm.

The method may comprise operation S518 of performing LDD implantation to form a LDD region in the substrate. In a case where the FET is an n-channel FET, an impurity, such as arsenic, may be implanted at an energy of about 10 keV-200 keV and at a dose of 1E13 cm⁻²-1E15 cm⁻². In a case where the FET is a p-channel FET, an impurity, such as BF₂, may be implanted at an energy of about 10 keV-200 keV and at a dose of 1E13 cm⁻²-1E15 cm⁻².

Then, the method may proceed to operation S520 of deposing an un-doped polysilicon layer. The polysilicon layer may have a thickness of about 50 nm-200 nm.

Next, the method may proceed to operation S522 of dry etching the polysilicon and the gate dielectric anisotropically, so that portions of the polysilicon at a position where the bulge and a top surface of the substrate with the bulge formed thereon join each other form gates, and portions of the gate dielectric between the gate and the bulge and also between the gate and the top surface of the substrate with the bulge formed thereon form a gate dielectric layer. In etching the polysilicon, the etching depth may be about 1.2-1.5 times the thickness of the deposited polysilicon layer. In etching the gate dielectric, the etching depth may be substantially the thickness of the gate dielectric, with an over etching of about 10%.

Then, the method may proceed to operation S524 of performing source/drain implantation to form a source on the bulge and to form a drain in the substrate on opposite sides of the bulge.

The source and drain may be made at the same time by the implantation, and are both heavily doped regions.

In a case where the FET is an n-channel FET, an impurity, such as arsenic, may be implanted at an energy of about 10 keV-200 keV and at a dose of 1E15 cm⁻²-5E15 cm⁻². In a case where the FET is a p-channel FET, an impurity, such as BF₂, may be implanted at an energy of about 10 keV-200 keV, and at a dose of 1E15 cm⁻²-5E15 cm⁻².

After operation S524, the method may further comprise performing fast annealing on the resultant device at a temperature of about 1000° C.-1050° C. for about 5-10 seconds, to repair implanting damage and/or activate the implanted impurities.

The FET shown in FIG. 3 can be manufactured by the same process as described above, except that operations S522 and S524 can be different.

Specifically, in operation S522, only a portion of the polysilicon layer at a position where the bulge and the top surface of the substrate with the bulge formed thereon join each other on a single side of the bulge forms a one-sided gate, and portions of the gate dielectric between the one-sided gate and the bulge and also between the one-sided gate and the top surface of the substrate with the bulge formed thereon form a one-sided gate dielectric layer.

In operation S524, a one-sided source is formed in the substrate at a location below, but laterally offset from, the bulge only on a single side of the bulge corresponding to the one-sided gate.

It is to be understood that the method may comprise further processes, such as formation of contact holes, formation of interconnects, and passivation, after the fast annealing. Those processes may be the same as those in the relevant art, and thus detailed descriptions thereof are omitted here.

From the foregoing, it will be appreciated that specific embodiments of the disclosure have been described herein for purposes of illustration, but that various modifications may be made without deviating from the disclosure. In addition, many of the elements of one embodiment may be combined with other embodiments in addition to or in lieu of the elements of the other embodiments. Accordingly, the technology is not limited except as by the appended claims.

1. A Field Effect Transistor (FET), comprising:
a substrate with a bulge formed on a top surface thereof;
a source and a drain, one of which is formed on the bulge formed on the top surface of the substrate, and the other of which is formed in the substrate at a location below, but laterally offset from the bulge;
a gate formed at a position where the bulge and the top surface of the substrate join each other; and
a gate dielectric layer formed between the gate and the bulge and also between the gate and the top surface of the substrate.

2. The FET according to claim 1, further comprising a well region formed in the substrate, wherein the source or drain, whichever is formed in the substrate at the location below, but laterally offset from the bulge, is formed in the well region.

3. The FET according to claim 1, further comprising a lightly doped drain (LDD) region formed in the substrate at a location below a portion of the gate dielectric layer between the gate and the top surface of the substrate, wherein the source or drain, whichever is formed in the substrate at the location below, but laterally offset from the bulge, is formed on an outer side of the LDD region.

4. The FET according to claim 1, wherein the source or drain, whichever is formed in the substrate at the location below, but laterally offset from the bulge, has a top surface substantially flush with the top surface of the substrate.

5. The FET according to claim 1, wherein the source or drain, whichever is formed in the substrate at the location below, but laterally offset from, the bulge, is below but laterally offset from the gate dielectric layer.

6. The FET according to claim 5, wherein the source is formed on the bulge, and the drain is formed in the substrate at a location below, but laterally offset from the gate dielectric layer.

7. The FET according to claim 6, wherein the gate, the gate dielectric layer and the drain are formed on a single side of the bulge, or wherein each of two said gates, two said gate dielectric layers and two said drains is formed on opposite sides of the bulge.

8. The FET according to claim 1, wherein the gate comprises polysilicon.

9. The FET according to claim 1, wherein the substrate comprises an n- or p-doped silicon based substrate or germanium based substrate.

10. The FET according to claim 1, wherein the bulge has a height of about 100 nm to 500 nm.

11. A method of manufacturing a Field Effect Transistor (FET), the method comprising:
forming a bulge on a substrate;
forming a gate at a position where the bulge and a top surface of the substrate joint each other, with a gate dielectric layer sandwiched between the gate and the bulge and also between the gate and the top surface of the substrate; and
forming one of a source and a drain of the FET on the bulge, and forming the other of the source and the drain in the substrate at a location below, but laterally offset from the bulge.

12. The method according to claim 11, further comprising forming a well region in the substrate, wherein forming the other of the source and the drain comprises forming it in the well region.

13. The method according to claim 11, further comprising forming a lightly doped drain (LDD) region in the substrate at a location below a portion of the gate dielectric layer between the gate and the top surface of the substrate, wherein forming the other of the source and the drain comprises forming it on an outer side of the LDD region.

14. The method according to claim 11, wherein forming one of the source and the drain comprises forming the source on the bulge, and forming the other of the source and the drain comprises forming the drain in the substrate at a location below but laterally offset from the gate dielectric layer.

15. The method according to claim 14,
wherein forming the gate comprises forming two gates on opposite sides of the bulge, with respective gate dielectric layers sandwiched between the respective gates and the bulge and also between the respective gates and the top surface of substrate, and
wherein forming the drain comprises forming each of two drains in the substrate, on opposite sides of the bulge, at a location below but laterally offset from the respective gate dielectric layer.

16. The method according to claim 11, further comprising performing fast annealing.

17. The method according to claim 11, further comprising performing implantation on the substrate with the bulge formed thereon for threshold voltage adjustment.

18. The method according to claim 11, wherein the gate comprises polysilicon.

19. The method according to claim 11, wherein the substrate comprises an n- or p-doped silicon based substrate or germanium based substrate.

20. The method according to claim 11, wherein the bulge has a height of about 100 nm to 500 nm.
